(19) United States
(12) Patent Application Publication
(10) Pub. No.: US 2014/0061841 A1
(43) Pub. Date: Mar. 6, 2014

(54) SEMICONDUCTOR PACKAGE

(71) Applicant: Samsung Electronics Co., Ltd., Suwon-Si (KR)

(72) Inventors: Youngbae KIM, Hwaseong-si (KR); Hyon-Chol KIM, Seoul (KR)

(73) Assignee: Samsung Electronics Co., Ltd., Suwon-Si (KR)

(21) Appl. No.: 13/956,666

(22) Filed: Aug. 1, 2013

(30) Foreign Application Priority Data
Aug. 30, 2012 (KR) 10-2012-0095588

(51) Int. Cl. H01L 31/02

(52) U.S. Cl. CPC H01L 31/02
USPC 257/443

(57) ABSTRACT

A semiconductor package including a substrate including an epoxy-based material, an image sensor chip mounted on the substrate, and an attaching part provided between the substrate and the image sensor chip may be provided. The attaching part may include a first attaching part, and a second attaching part provided around the first attaching part. The first attaching part may achieve high reliability of the semiconductor package in association with the second attaching part. The second attaching part may include a material having a low rigidity. Thus, it is possible to reduce or prevent warpage of the image sensor chip from occurring. Due to the presence of the second attaching part, a plane coverage ratio of the first attaching part relative to the image sensor chip can be reduced. Thus, the warpage of the image sensor chip can be reduced or prevented more effectively.

### CROSS-REFERENCE TO RELATED APPLICATIONS

This U.S. non-provisional patent application claims priority under 35 U.S.C. §119 to Korean Patent Application No. 10-2012-0095588, filed on Aug. 30, 2012, in the Korean Intellectual Property Office, the entire contents of which are hereby incorporated by reference.

### BACKGROUND OF THE INVENTION

Some of example embodiments of the inventive concepts relate to semiconductor packages, and in particular, to a complementary metal-oxide-semiconductor (CMOS) image sensor packages.

In general, an image sensor is configured to convert one-dimensional or two-dimensional optical information into electric signals. The image sensor may be classified into a CMOS image sensor and a charge-coupled device (CCD) image sensor. The image sensor can be applied to realize cameras, camcorders, multimedia personal computers, and/or security cameras, and demands for the image sensor are rapidly increasing.

A package for the CMOS image sensor may include a ceramic substrate. The ceramic substrate prevents or mitigates warpage of a semiconductor chip, and thus, the ceramic substrate is being used for high quality image sensor packages. However, in general, the ceramics substrate is expensive and difficult to process. A transparent compound or a lead frame molded with plastic may be used to package the CMOS image sensor. However, these materials have not been widely adopted so far because of several technical difficulties (e.g., a problem related to an assembling process or a definition issue caused by moisture-absorption).

### SUMMARY

Example embodiments of the inventive concepts provide semiconductor packages having an improved warpage property and improved reliability.

According to an example embodiments of the inventive concepts, a semiconductor package may include an image sensor chip mounted on a substrate, an attaching part interposed between the substrate and the image sensor chip, a holder provided on the substrate and surround a side surface of the image sensor chip, and a transparent cover provided on the holder and spaced apart from the substrate and facing the substrate. The attaching part may include a first attaching part, and a second attaching part provided to cover or surround at least a side surface of the first attaching part and the second attaching part has a rigidity lower than the first attaching part.

The first attaching part may include at least one of a polyimide-based material and an epoxy-based material.

The first attaching part may include a first surface being in contact with the image sensor chip, a second surface being in contact with the substrate, and a side surface connecting the first surface to the second surface and being in contact with the second attaching part.

The substrate may include an epoxy-based material.

The semiconductor package may further include a bonding wire connecting the image sensor chip to an internal pad provided on the substrate and electrically connecting the image sensor chip to the substrate.

The transparent cover may be hermitically combined with the holder to define a void between the substrate and the transparent cover.

According to an example embodiment of the inventive concepts, a semiconductor package may include a substrate having first and second surfaces facing each other and including an epoxy-based material, an image sensor chip provided on the first surface of the substrate, an attaching part provided between the first surface of the substrate and the image sensor chip and including a first attaching part and a second attaching part, a bonding wire connecting the image sensor chip to the substrate, a holder attached to an edge of the first surface of the substrate, and a transparent cover provided on the holder. The first attaching part may be in contact with the image sensor chip at a center thereof, the second attaching part may be in contact with the image sensor chip an edge thereof, and the second attaching part may include a material, whose modulus is lower than that of the first attaching part.

The first attaching part may include at least one of a polyimide-based materials and an epoxy-based material.

According to an example embodiment, a semiconductor package, an image sensor chip on the substrate, a first attaching layer coupling the substrate to the semiconductor chip at the center portion of the semiconductor chip, and a second attaching layer filling a space defined between the substrate, the semiconductor chip, and the first attaching layer. At least a portion of the second attaching layer is coupled to a side surface of the first attaching layer and the second attaching layer is less rigid than the first attaching layer. The substrate may include a substrate including an epoxy-based material

The semiconductor package may further include a transparent cover over the image sensor chip. The semiconductor package may further include a void hermitically defined between the transparent cover and the image sensor chip. The semiconductor package may further include a holder being coupled to the substrate at an edge of the substrate, the holder surrounding at least a side surface of the image sensor chip and supporting the transparent cover.

The first attaching layer may include at least one of a polyimide-based material or an epoxy-based material.

The first attaching layer and the second attaching layer may form an attaching structure, which has a trapezoidal cross-section.

The first attaching layer may be formed to have one of a square shape, an elliptical shape, a cross shape, a letter x shape, and a star-like shape in a plan view.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor package according to an example embodiment of the inventive concepts.

FIG. 2 is a cross-sectional view taken along a line II-II′ of FIG. 1.

FIG. 3 is an enlarged plan view of a portion III of FIG. 1.

FIG. 4 is a graph showing a warpage property of an image sensor chip with respect to a modulus value of a second attaching part, in a comparative example and experimental examples.

FIG. 5 is a graph showing a warpage property of an image sensor chip with respect to a surface coverage ratio of a first attaching part relative to an image sensor chip, in a comparative example and experimental examples.

FIGS. 6 through 10 are plan views illustrating a semiconductor package according to other example embodiments of the inventive concepts.

FIGS. 11A through 11D are cross-sectional views illustrating a method of fabricating a semiconductor package according to an example embodiment of the inventive concepts.

FIG. 12 is a schematic diagram illustrating an example of a package module including a semiconductor package according to example embodiments of the inventive concepts.

FIG. 13 is a perspective view illustrating an example of an electronic apparatus including a semiconductor package according to example embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which the example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein, but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

[Semiconductor Packages]

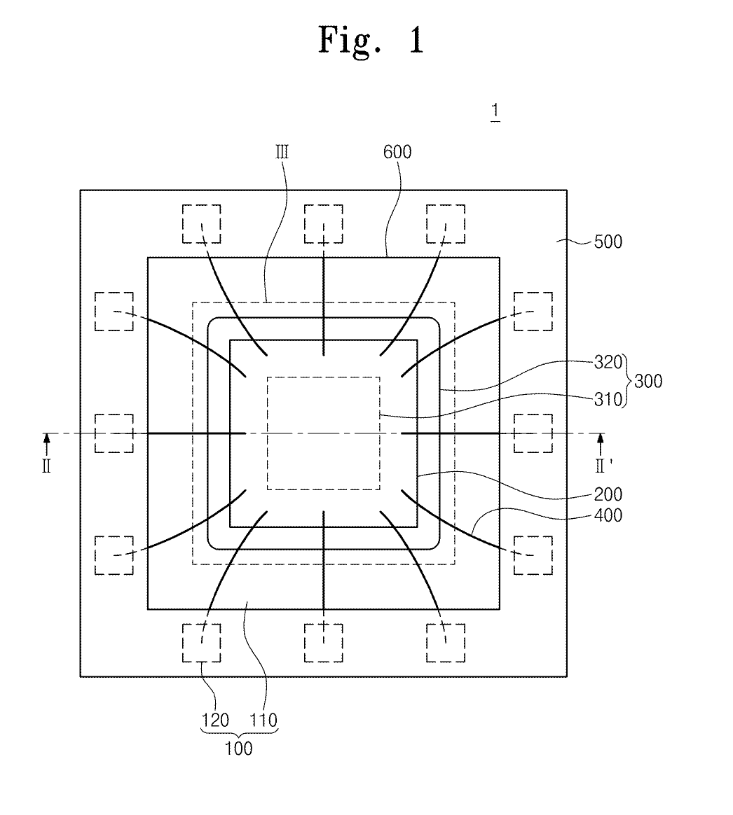

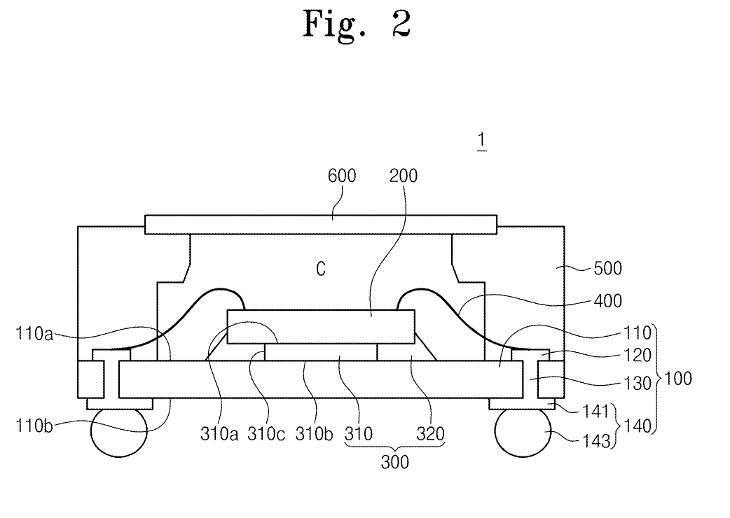

FIG. 1 is a plan view illustrating a semiconductor package according to an example embodiment of the inventive concepts, and FIG. 2 is a sectional view taken along a line II-II′ of FIG. 1.

Referring to FIGS. 1 and 2, a semiconductor package 1 may include a substrate 100, an image sensor chip 200 mounted on the substrate 100, an attaching part 300 interposed between the substrate 100 and the image sensor chip 200, a bonding wire 400, a holder 500, and/or a transparent cover 600. A void C may be provided between the image sensor chip 200 and the transparent cover 600.

The substrate 100 may be a printed circuit board (PCB), in which patterns are provided. The substrate 100 may include a first surface 100a and a second surface 100b, which face each other. The substrate 100 may include a base substrate 110, an internal pad 120, a through via 130, and/or an outer connecting terminal 140. The base substrate 110 may include an epoxy-based material and/or a ceramics material. The base substrate 110 may have a thermal expansion coefficient of about 17 ppm/° C. The internal pad 120 may be provided on the first surface 100a of the substrate 100 and include a conductive material. The through via 130 may be provided through the substrate 100, thereby reducing an overall size (e.g., height) of the semiconductor package 1, thereby increasing a signal delivering speed. For example, the through via 130 may be formed through the substrate 100 to connect the first surface 100a with the second surface 100b. The through via 130 may include a conductive material (e.g., W, Ti, Ni, Cu, Au, Ti/Cu, Ti/Ni and/or alloys thereof). The through via 130 may be configured to connect the internal pad 120 to the outer connecting terminal 140 provided on the second surface 100b. The outer connecting terminal 140 may include an outer pad 141 and/or a solder ball 143 provided on the outer pad 141. Each of the outer pad 141 and the solder ball 143 may include a conductive material. The outer connecting terminal 140 may be configured to electrically connect the semiconductor package 1 to an external electronic device (e.g., a motherboard).

The image sensor chip 200 may include a CMOS image sensor (CIS) chip. The image sensor chip 200 may be configured to convert optical signals obtained from a subject into electrical signals.

The attaching part 300 may be provided between the substrate 100 and the image sensor chip 200 to couple the substrate 100 to the image sensor chip 200. The attaching part 300 may include a first attaching part 310 and a second attaching part 320. The first attaching part 310 may include a first surface 310a being in contact with the image sensor chip, a second surface 310b being in contact with the substrate 100, and a side surface 310c connecting the first surface 310a to the second surface 310b. At least a portion of the second attaching part 320 may be in contact with the side surface 310c of the first attaching part 310.

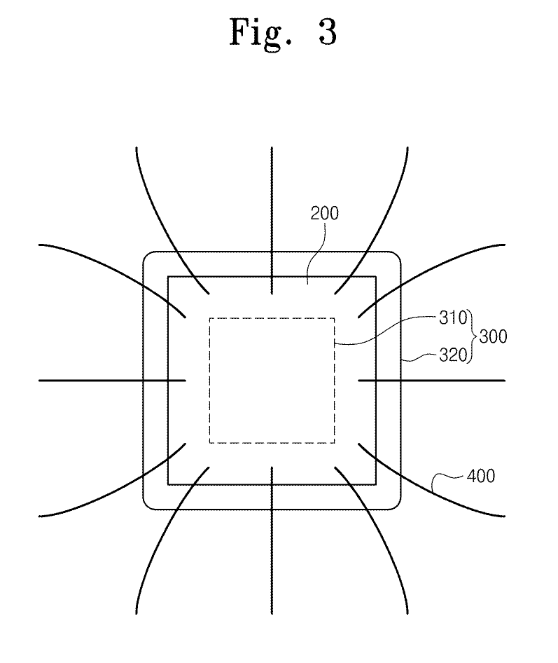

FIG. 3 is an enlarged plan view of a portion III of FIG. 1.

Referring to FIG. 3, the first attaching part 310 may be provided as an internal portion of the attaching part 300, and the second attaching part 320 may be provided to cover or surround the first attaching part 310. The first attaching part 310 may be provided to be in contact a core or center portion of the image sensor chip 200, and the second attaching part 320 may be provided to be in contact with an edge of the image sensor chip 200. The first attaching part 310 may include a photo-sensitive polymer, an adhesive polymer, and/or thermosetting polymer. For example, the first attaching part 310 may include a polyimide-based material and/or an epoxy-based material. The second attaching part 320 may include a material, whose rigidity (e.g., modulus or yield stress) is lower than that of the first attaching part 310.

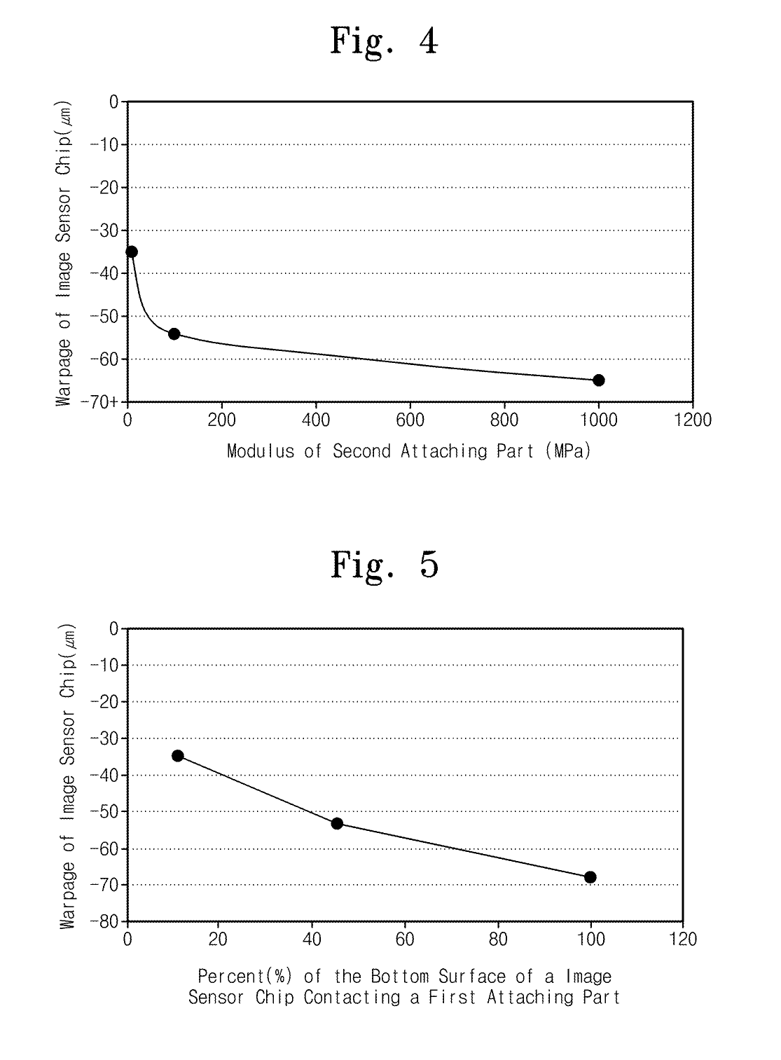

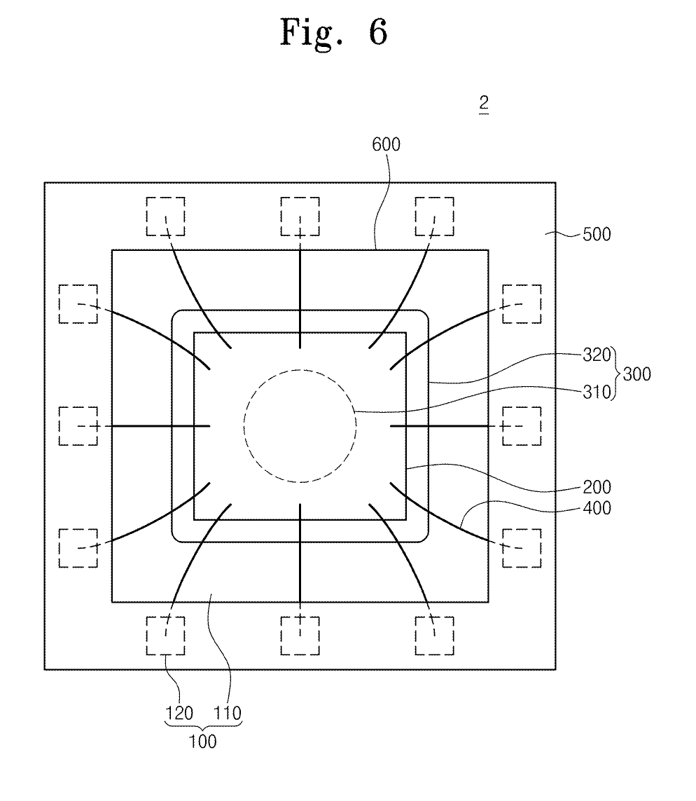

FIG. 4 is a graph showing a warpage property of an image sensor chip with respect to a modulus value of a second attaching part, in a comparative example and experimental examples. FIG. 5 is a graph showing a warpage property of an image sensor chip with respect to percent (%) of the bottom surface of the image sensor chip contacting the first attaching part, in a comparative example and experimental examples. In the comparative example, a semiconductor package was configured to include the first attaching part 310. In the experimental examples 1 through 6, semiconductor packages were configured to include the first attaching part 310 and the second attaching part 320 and to have the structure shown in FIG. 1. Table 1 shows simulation results that were performed on the comparative and experimental examples under a temperature condition of 25° C.

TABLE 1

| | Percent (%) | | |
|---|---|---|---|
| | of the bottom | | |
| | surface of a | Modulus of a | |
| | image sensor | second | Warpage of an |
| | chip contacting a first | attaching | image sensor chip |
| | attaching part | part (MPa) | (μm) |
| Comparative | 100 | 9 | −66 |
| example | | | |
| Experimental | 45 | 10 | −53 |
| example 1 | | | |
| Experimental | 45 | 100 | −59 |
| example 2 | | | |
| Experimental | 45 | 1000 | −65 |
| example 3 | | | |
| Experimental | 11 | 10 | −35 |
| example 4 | | | |
| Experimental | 11 | 100 | −54 |
| example 5 | | | |
| Experimental | 11 | 1000 | −65 |
| example 6 | | | |

Referring to Table 1 and FIG. 4, the warpage of the image sensor chip 200 is more suppressed in the experimental examples than in the comparative example. Further, in the experimental examples 1 through 6, the warpage of the image sensor chip 200 was reduced as the modulus value of the second attaching part 320 decreases. The warpage of the image sensor chip 200 may result from a stress caused by a difference in thermal expansion coefficient between the substrate 100 and the image sensor chip 200. If the base substrate 110 is formed of an epoxy-based material, it may have a thermal expansion coefficient of about 17 ppm/° C. If the base substrate 110 is formed of a ceramic-based material, it may have a thermal expansion coefficient of about 3 μm/° C. This means that the warpage property of the image sensor chip 200 may be deteriorated where the base substrate 110 is formed of the epoxy-based material than where the base substrate 110 is formed of the ceramic-based base substrate 110. The second attaching part 320 may buffer the stress caused by a difference in thermal expansion coefficient. Addressing the then stress issue using the attaching part 300 according to an example embodiment of the inventive concepts, the semiconductor package 1 may use the base substrate 110 including the epoxy-based material, instead of the ceramic-based material.

According to an example embodiment of the inventive concepts, the attaching part 300 may be configured to have a structure capable of preventing the warpage of the image sensor chip 200 from occurring. For example, the attaching part 300 may be formed to have a trapezoidal cross-section. The plane coverage between the attaching part 300 and the image sensor chip 200 may also be adjusted. Referring to Table 1 and FIG. 5, the warpage of the image sensor chip 200 was reduced as the plane coverage between the first attaching part 310 and the image sensor chip 200 decreases. Because the attaching part 300 is configured to include the second attaching part 320, coverage between the first attaching part 310 and the image sensor chip 200 can be reduced more effectively. Accordingly, it is possible to prevent the warpage of the image sensor chip 200 from occurring.

The first attaching part 310 may achieve high reliability of the semiconductor package 1 in association with the second attaching part 320. The second attaching part 320 of the attaching part 300 may be formed of a material exhibiting a modulus and/or yield stress value being lower than those of the first attaching part 310. Thus, the warpage of the image sensor chip 200 can be reduced. Further, the use of the second attaching part 320 may make it possible to use the epoxy-based material, which has a relatively high thermal expansion coefficient, as a material for the substrate 100 of the semiconductor package 1. Accordingly, it is possible to reduce a fabrication cost of the semiconductor package 1 and process the substrate 100 with relative ease.

Referring back to FIGS. 1 and 2, a plurality of the bonding wires 400 may be provided. The bonding wires 400 may connect the image sensor chip 200 to the internal pads 120 of the substrate 100. The image sensor chip 200 may be electrically connected to the substrate 100 and an external electronic device via the bonding wires 400. The bonding wires 400 may include at least one of gold (Au), aluminum (Al), copper (Cu), and alloys thereof.

The holder 500 may be provided on an edge of the first surface 100a of the substrate 100. The holder 500 may be provided to surround the image sensor chip 200. The holder 500 may be attached to the substrate 100 to support the transparent cover 600. The holder 500 may protect the image sensor chip 200. The holder 500 may include a dielectric material. For example, the holder 500 may include a silicone polymer material.

The transparent cover 600 may be provided on the holder 500 and be spaced apart from and face the image sensor chip 200. The transparent cover 600 may be hermetically combined with the holder 500 to define a void C between the transparent cover 600 and the image sensor chip 200. For example, the transparent cover 600 may be formed of a transparent material (e.g., glass). The transparent cover 600 may be configured to serve as an infrared light (IR) filter. The transparent cover 600 may be configured to prevent the image sensor chip 200 from being polluted. Further, due to the presence of the transparent cover 600, pollutants (e.g., particles) on the transparent cover 600 can be removed by a user without substantially damaging the image sensor chip 200.

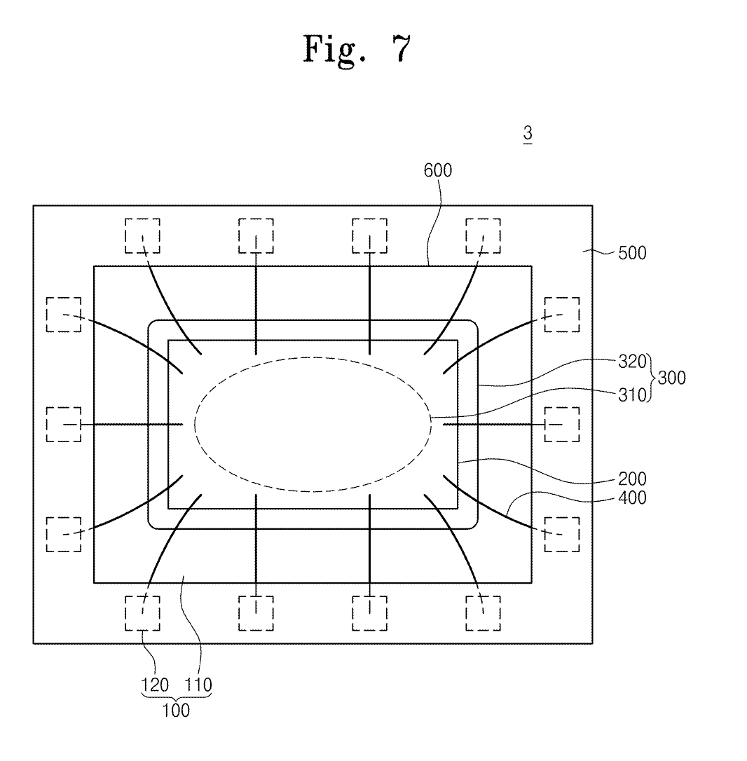

FIGS. 6 through 10 are plan views illustrating a semiconductor package according to other example embodiments of the inventive concepts. For the sake of brevity, the elements and features of this example that are similar to those previously shown and described will not be described in much further detail.

Referring to FIG. 6, a semiconductor package 2 may include an attaching part 300. The attaching part 300 may include a first attaching part 310 and a second attaching part 320. The first attaching part 310 may be provided as an internal portion of the attaching part 300. The first attaching part 310 may have a circular shape in a plan view. The second attaching part 320 may surround the first attaching part 310.

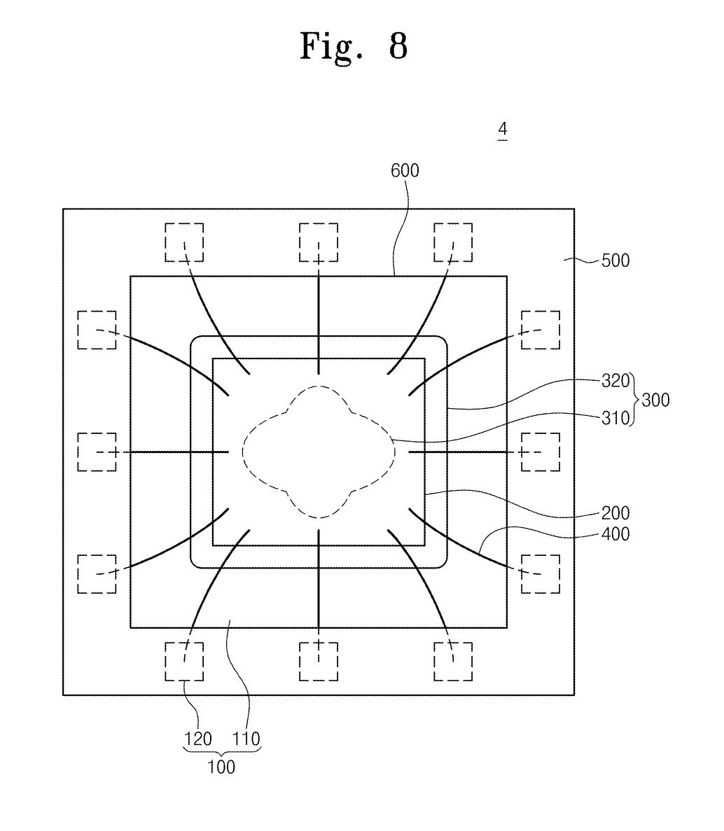

Referring to FIG. 7, a semiconductor package 3 may include an attaching part 300. The attaching part 300 may include a first attaching part 310 and a second attaching part 320. The first attaching part 310 may be provided as an internal portion of the attaching part 300 and have an elliptical shape in a plan view.

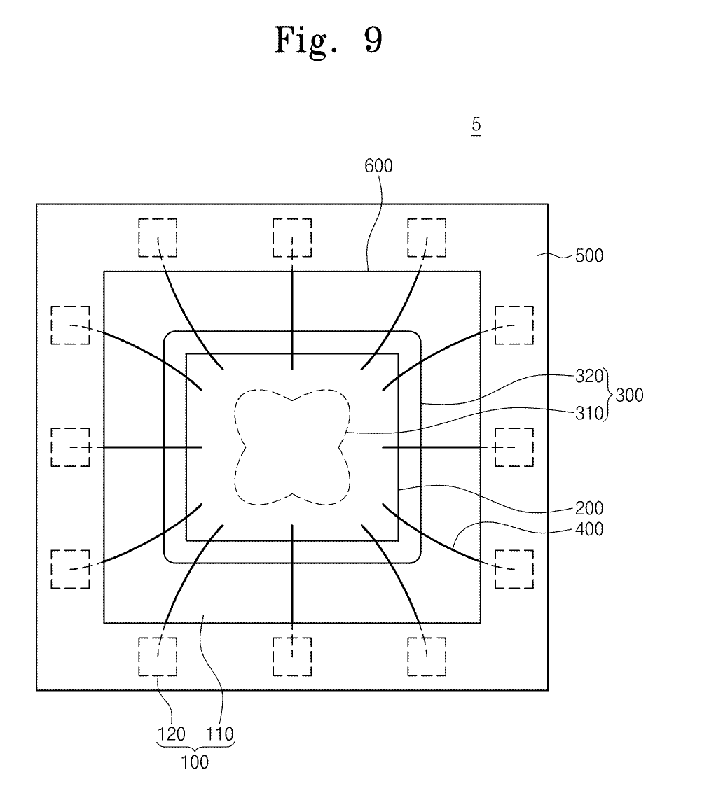

Referring to FIG. 8, a semiconductor package 4 may include an attaching part 300. The attaching part 300 may include a first attaching part 310 and a second attaching part 320. The first attaching part 310 may be provided as an internal portion of the attaching part 300. The first attaching part 310 may have a cross shape, in a plan view.

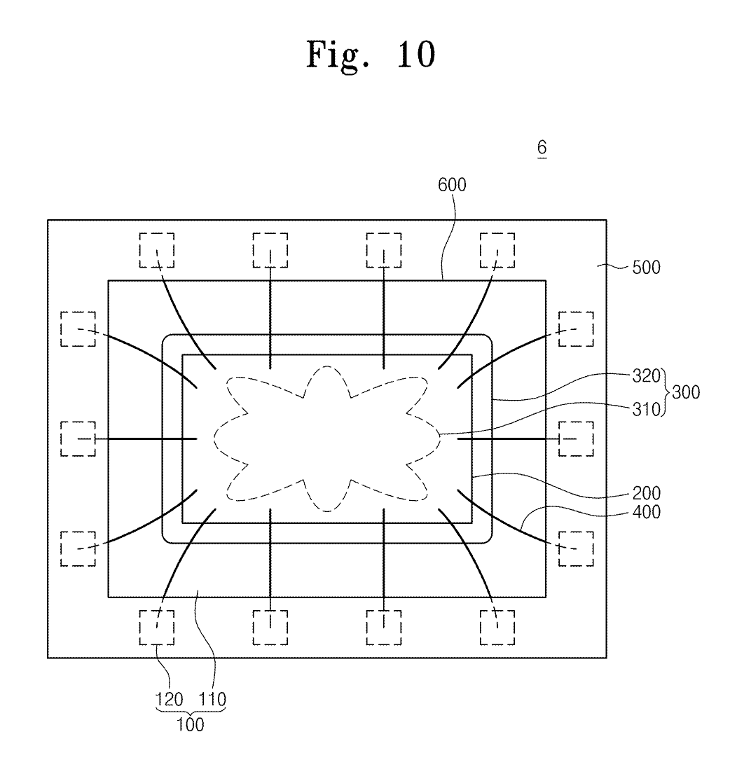

Referring to FIG. 9, a semiconductor package 5 may include an attaching part 300. The attaching part 300 may include a first attaching part 310 and a second attaching part 320. The first attaching part 310 may be provided as an internal portion of the attaching part 300 and have a letter ‘x’ shape in a plan view.

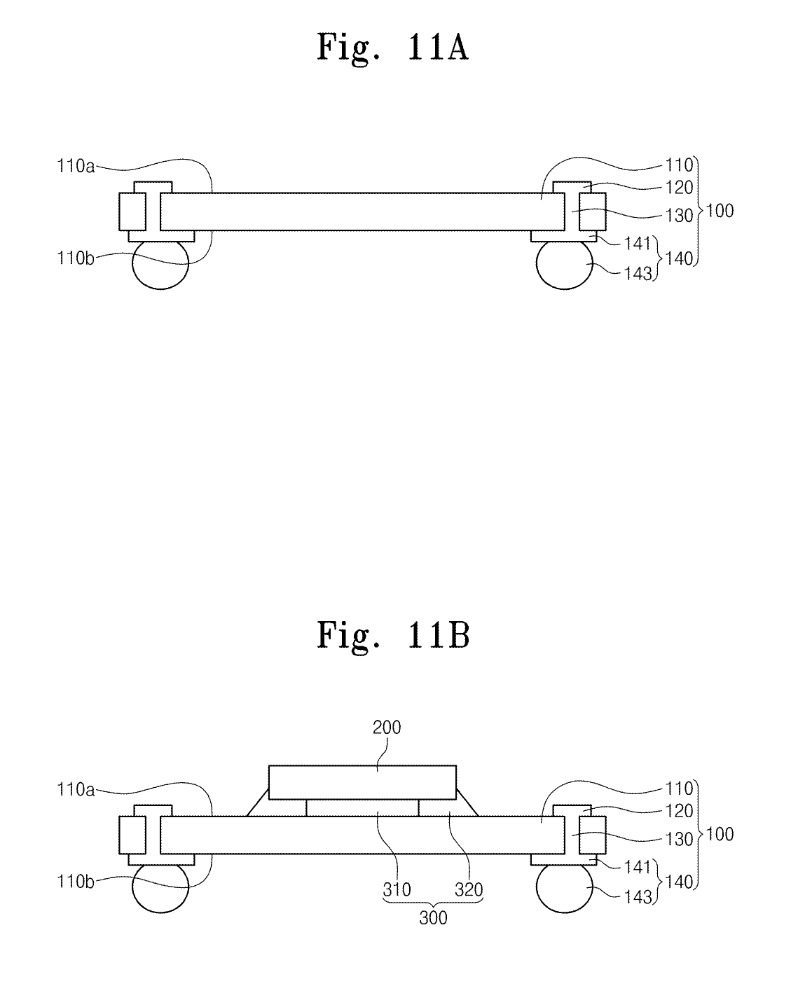

Referring to FIG. 10, a semiconductor package 6 may include an attaching part 300. The attaching part 300 may include a first attaching part 310 and a second attaching part 320. The first attaching part 310 may have a star-like shape, which may be made by, for example, overlapping a cross shape on a letter x shape in a plan view.

[Methods of Fabricating a Semiconductor Package]

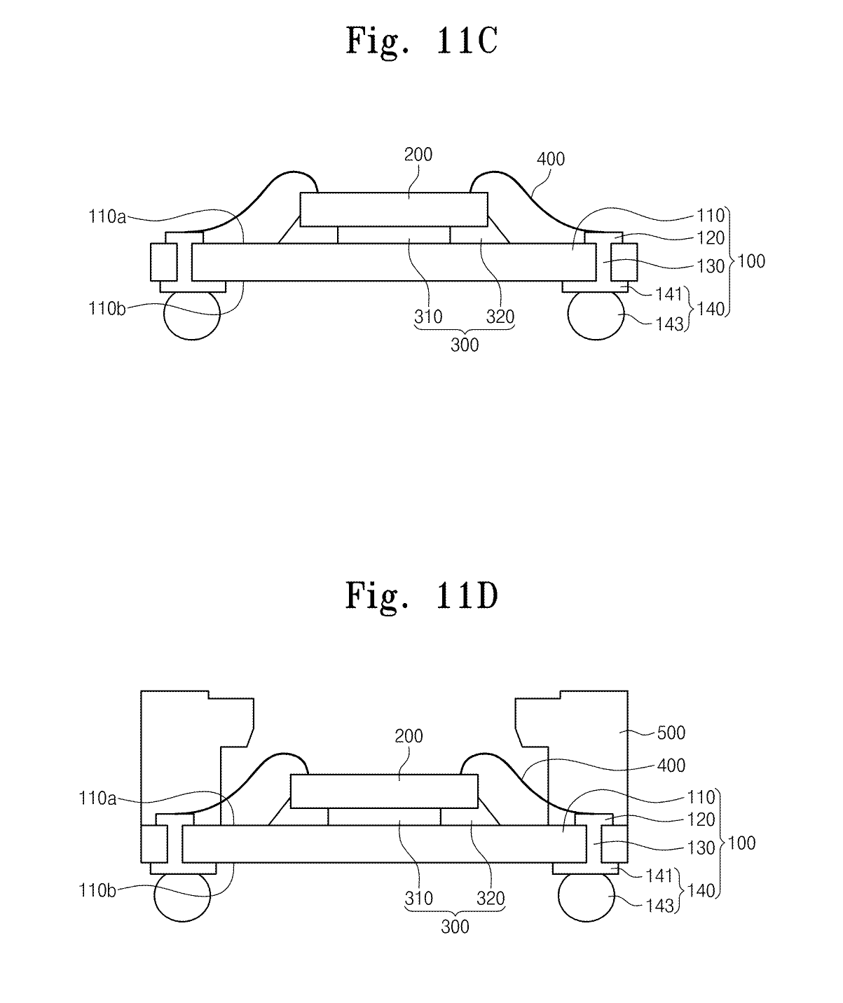

FIGS. 11A through 11D are cross-sectional views illustrating a method of fabricating a semiconductor package according to an example embodiment of the inventive concepts. For the sake of brevity, the elements and features of this example that are similar to those previously shown and described will not be described in much further detail.

Referring to FIG. 11A, a substrate 100 may be provided. The substrate 100 may include a first surface 100a and a second surface 100b facing each other. An internal pad 120 may be formed on the first surface 100a of the substrate 100. An outer connecting terminal 140 with an outer pad 141 and/or a solder ball 143 may be formed on the second surface 100b of the substrate 100. A through via 130 may be formed through the substrate 100 to electrically connect the internal pad 120 to the outer connecting terminal 140. The formation of the through via 130 may include forming a through hole and filling the through hole with a conductive material. The through hole may be formed using a dry etching process, a wet etching process, and/or a laser punching process. For example, the through via 130 or the conductive material filling the through hole may include at least one of W, Ti, Ni, Cu, Au, Ti/Cu. Ti/Ni and/or alloys thereof. The filling of the conductive material may be performed using a sputtering process, a chemical vapor deposition, and/or an electroplating process.

Referring to FIG. 11B, an image sensor chip 200 may be attached on the first surface 100a of the substrate 100. A first attaching part 310 may be formed on the first surface 100a of the substrate 100. The first attaching part 310 may include a polyimide-based and/or an epoxy-based material. A second attaching part 320 may be formed to surround the first attaching part 310. The second attaching part 320 may include a material, whose rigidity (e.g., modulus or yield stress) is lower than that of the first attaching part 310. The image sensor chip 200 may be stacked on the attaching part 300. For example, the stacking of the image sensor chip 200 may be performed using a thermo compression process to fill a gap between the image sensor chip 200 and the substrate 100 with the first attaching part 310 and the second attaching part 320. A thickness and a shape of the attaching part 300, a plane coverage ratio of the attaching part 300 relative to the image sensor chip 200, a ratio between the plane coverage ratio of the first attaching part 310 relative to the image sensor chip 200 to a plane coverage ratio of the second attaching part 320 relative to the image sensor chip 200 may be adjusted.

Referring to FIG. 11C, a bonding wire 400 may be formed to connect the image sensor chip 200 electrically to the internal pad 120 of the substrate 100. The bonding wire 400 may include at least one of gold (Au), aluminum (Al), copper (Cu), and/or alloys thereof Referring to FIG. 11D, a holder 500 may be formed on the first surface 100a of the substrate 100. The holder 500 may be formed to surround the image sensor chip 200. The holder 500 may include a dielectric material (e.g., silicone polymer). For example, the holder 500 may be formed by curing a liquid polymer material.

Referring back to FIG. 1, the transparent cover 600 may be provided on the holder 500. The transparent cover 600 may be hermetically sealed, combined or coupled with the holder 500 to define the void C. The void C may be formed between the transparent cover 600 and the image sensor chip 200. The hermetical combination between the holder 500 and the transparent cover 600 may be realized using an adhesives or glue layer.

According to some example embodiments of the inventive concepts, the semiconductor package 1 may be fabricated by attaching the image sensor chip 200 on the substrate 100 and forming the holder 500 and the transparent cover 600. However, in other embodiments, a plurality of the semiconductor packages 1 may be simultaneously fabricated.

[Application]

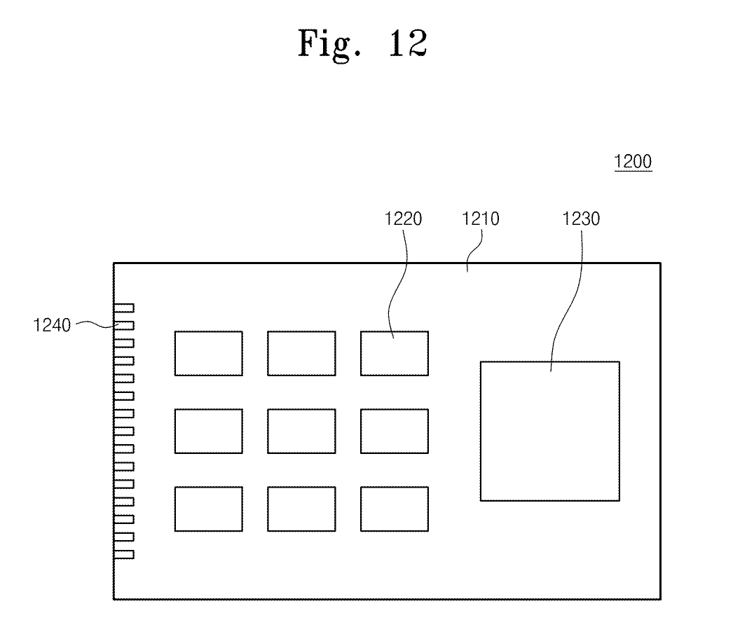

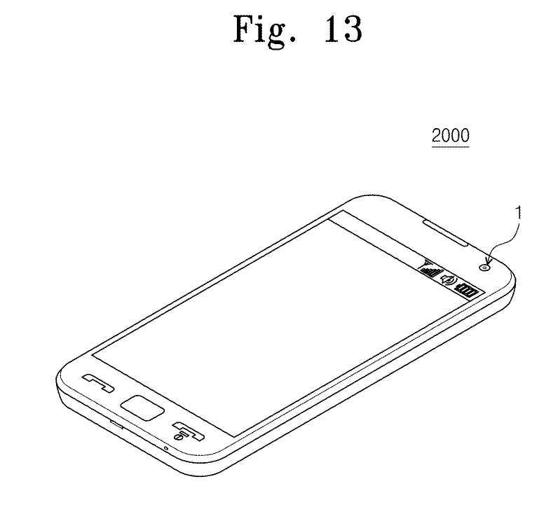

FIG. 12 is a schematic diagram illustrating an example of a package module including a semiconductor package according to example embodiments of the inventive concepts. FIG. 13 is a perspective view illustrating an example of an electronic apparatus including a semiconductor package according to example embodiments of the inventive concepts.

Referring to FIG. 12, a package module 1200 may include semiconductor devices 1220 and a semiconductor device 1230 packaged in a quad flat package (QFP) type. Each or all of the semiconductor devices 1220 and 1230 may include at least one of the semiconductor packages 1 through 6 according to example embodiments of the inventive concepts. The package module 1200 may be connected to an external electronic device through an external connection terminal 1240 disposed at one side of a substrate 1210.

Referring to FIG. 13, a mobile phone 2000 may include at least one of the semiconductor packages 1 through 6 according to example embodiments of the inventive concepts. For example, at least one of the semiconductor packages 1 through 6 may be used in a digital camera portion, which is installed in the mobile phone 2000. In some embodiments, the semiconductor packages 1 through 6 may be provided in an electronic device (e.g., a camera, a camcorder, a personal digital assistant (PDA), a wireless phone, a laptop computer, an optical mouse, a facsimile, or a copying machine). In other embodiments, the semiconductor packages 1 through 6 may be provided in a telescope, a mobile phone handset, a scanner, an endoscope, a fingerprint-identification system, a toy, a game console, a home robot, a car, and the like.

According to example embodiments of the inventive concepts, a semiconductor package may include an attaching part provided between a substrate made of an epoxy-based material and an image sensor chip, and the attaching part may include a first attaching part and a second attaching part. The first attaching part may achieve high reliability of the semiconductor package in association with the second attaching part. The first attaching part may be an internal portion of the attaching part, and the second attaching part may surround the first attaching part. The second attaching part may include a material having a low rigidity, and thus, it is possible to reduce or prevent warpage of the image sensor chip from occurring. Because the attaching part may further include the second attaching part, coverage between the first attaching part and the image sensor chip can be reduced. Thus, the warpage of the image sensor chip can be reduced or prevented more effectively.

While example embodiments of the inventive concepts have been particularly shown and described, it will be understood by one of ordinary skill in the art that variations in form and detail may be made therein without departing from the spirit and scope of the attached claims and their equivalents.

What is claimed is:

1. A semiconductor package, comprising:
an image sensor chip mounted on a substrate;
an attaching part interposed between the substrate and the image sensor chip, the attaching part including,
a first attaching part, and
a second attaching part covering at least a side surface of the first attaching part, the second attaching part having a rigidity lower than the first attaching part;
a holder provided on the substrate, the holder surrounding a side surface of the image sensor chip; and
a transparent cover provided on the holder and spaced apart from the substrate, the transparent cover facing the image sensor chip.

2. The semiconductor package of claim 1, wherein the first attaching part includes at least one of a polyimide-based material and an epoxy-based material.

3. The semiconductor package of claim 1, wherein the first attaching part comprises:
a first surface in contact with the image sensor chip;
a second surface in contact with the substrate; and
a side surface connecting the first surface to the second surface, and wherein the second attaching part is in contact with the side surface of the first attaching part.

4. The semiconductor package of claim 1, wherein the substrate includes an epoxy-based material.

5. The semiconductor package of claim 1, further comprising:
a bonding wire connecting the image sensor chip to an internal pad provided on the substrate, the bonding wire electrically connecting the image sensor chip to the substrate.

6. The semiconductor package of claim 1, wherein the transparent cover is hermitically combined with the holder to define a void between the substrate and the transparent cover.

7. A semiconductor package, comprising:
a substrate having first and second surfaces, the first and second surfaces facing each other, and the substrate including an epoxy-based material;
an image sensor chip provided on the first surface of the substrate;
an attaching part provided between the first surface of the substrate and the image sensor chip, the attaching part including a first attaching part and a second attaching part, the first attaching part being in contact with the image sensor chip at a center thereof, the second attaching part being in contact with the image sensor chip at an edge thereof, and the second attaching part including a material, the modulus of the material being lower than the first attaching part;
a bonding wire connecting the image sensor chip to the substrate;
a holder attached to an edge of the first surface of the substrate; and
a transparent cover provided on the holder.

8. The semiconductor package of claim 7, wherein the first attaching part includes at least one of a polyimide-based material and an epoxy-based material.

9. A semiconductor package, comprising:
a substrate;
an image sensor chip on the substrate;
a first attaching layer coupling the substrate to the semiconductor chip at the center portion of the semiconductor chip; and
a second attaching layer filling a space defined between the substrate, the semiconductor chip, and the first attaching layer, at least a portion of the second attaching layer being coupled to a side surface of the first attaching layer, and the second attaching layer being less rigid than the first attaching layer.

10. The semiconductor package of claim 9, wherein the substrate includes an epoxy-based material.

11. The semiconductor package of claim 9, further comprising:
a transparent cover over the image sensor chip.

12. The semiconductor package of claim 11, wherein:
the transparent cover and the image sensor chip hermitically define a void.

13. The semiconductor package of claim 11, further comprising:
a holder being coupled to the substrate at an edge thereof, the holder surrounding at least a side surface of the image sensor chip and supporting the transparent cover.

14. The semiconductor package of claim 9, wherein the first attaching layer includes at least one of a polyimide-based material and an epoxy-based material.

15. The semiconductor package of claim 9, wherein the first attaching layer and the second attaching layer form an attaching structure, the attaching structure having a trapezoidal cross-section.

16. The semiconductor package of claim 9, wherein the first attaching layer is formed to have one of a square shape, an elliptical shape, a cross shape, an x shape, and a star-like shape in a plan view.
